(19) United States
(12) Patent Application Publication
(10) Pub. No.: US 2026/0130224 A1
(43) Pub. Date: May 7, 2026

(54) INTEGRATED CIRCUIT PACKAGE STRUCTURE AND MANUFACTURING METHOD THEREOF

(71) Applicant: Taiwan Semiconductor Manufacturing Company, Ltd., Hsinchu (TW)

(72) Inventors: Bo-Yu Chiu, Taoyuan City (TW); Hong-Seng Shue, Hsinchu County (TW); Steven Sze Hang Poon, Hsinchu City (TW); Chih-Yu Chou, Hsinchu City (TW); Wei-Chao Chang, Hsinchu County (TW)

(73) Assignee: Taiwan Semiconductor Manufacturing Company, Ltd., Hsinchu (TW)

(21) Appl. No.: 18/937,030

(22) Filed: Nov. 5, 2024

(51) Int. Cl. H01L 23/60; H01L 23/00; H01L 23/498; H01L 23/538; H01L 23/64; H01L 25/065; H01L 27/02; H10B 80/00

(52) U.S. Cl. CPC H10W 42/60; H10D 89/60; H10W 44/601; H10B 80/00; H10W 70/611; H10W 70/65; H10W 72/072; H10W 72/073; H10W 72/241; H10W 74/15; H10W 90/00; H10W 90/401; H10W 90/724; H10W 90/734

(57) ABSTRACT

An integrated circuit package structure includes a first substrate and a second substrate. The first substrate includes a sensor and a metal routing connecting to the sensor. The second substrate is bonded to the first substrate and includes a circuit layer and a plurality of conductive connectors connecting to the circuit layer. At least one of the first substrate and the second substrate further includes a stacked metal structure configured to provide electrostatic discharge protection.

### BACKGROUND

Extremely high voltages can develop in the vicinity of integrated circuits due to the build-up of static charges. A high potential may be generated to an input buffer or an output buffer of an integrated circuit. The high potential may be caused by a person touching a package pin that is in electrical contact with the input or the output buffer. When the electrostatic charges are discharged, a high current is produced at the package nodes of the integrated circuit. This phenomenon is referred to as electrostatic discharge. The electrostatic discharge is a serious problem for semiconductor devices since it can potentially destroy the entire integrated circuit.

The duration of the electrostatic discharge transient is very short, typically in the order of nanoseconds, and the conventional circuit breakers cannot react quickly enough to provide adequate protection. For this reason, it has become a known practice to incorporate electrostatic discharge devices in integrated circuits. Conventionally, bi-directional diode strings were coupled between the package pins to protect the respective circuit. Other electrostatic discharge devices such as transistors were also used. The electrostatic discharge devices were also widely used between power lines to protect the internal circuits coupled between the power lines and to discharge electrostatic discharge currents to the ground.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is schematic view illustrating an integrated circuit package structure in accordance with some embodiments of the disclosure.

FIG. 1B is a schematic cross-sectional view illustrating the integrated circuit package structure of FIG. 1A.

FIG. 1C is a schematic enlarged partial view illustrating the integrated circuit package structure of FIG. 1B.

FIG. 2 is a schematic cross-sectional view illustrating an integrated circuit package structure in accordance with some alternative embodiments of the disclosure.

FIG. 3 is a schematic cross-sectional view illustrating an integrated circuit package structure in accordance with some alternative embodiments of the disclosure.

FIG. 4 is a schematic cross-sectional view illustrating an integrated circuit package structure in accordance with some alternative embodiments of the disclosure.

FIG. 5 is a schematic cross-sectional view illustrating an integrated circuit package structure in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

For the test chip, sensors are placed for reliability verification. In the reliability test setup, the chip is placed on the FR4 (insulator) substrate between the charge plate and the ground plane of the pogo pin, and the sensor is configured inside the chip. The high voltage supply is provided voltage to the charge plate, and the pogo pin drives the current into the chip through high voltage pulses to test reliability of chip. However, due to cost and cycle time constraints, the test chip does not have corresponding grounds for the sensor, leading to severe daisy chain burnout that significantly affects yield, especially at nodes below N5 and in 2.5D and 3D packages. In the present embodiment, the integrated circuit package substrate achieves the electrostatic discharge protection by providing the current shunt path through the stacked metal structures to discharge the electrostatic discharge currents. In other words, the integrated circuit package structure of the present embodiment utilizes the special layout configuration to achieve electrostatic discharge protection even without the diode to ground. In brief, this embodiment utilizes fundamental electrostatic discharge concepts to design a structure with low impedance and high capacitance, thereby optimizing the charging distribution behavior and, consequently, indirectly protecting the sensor.

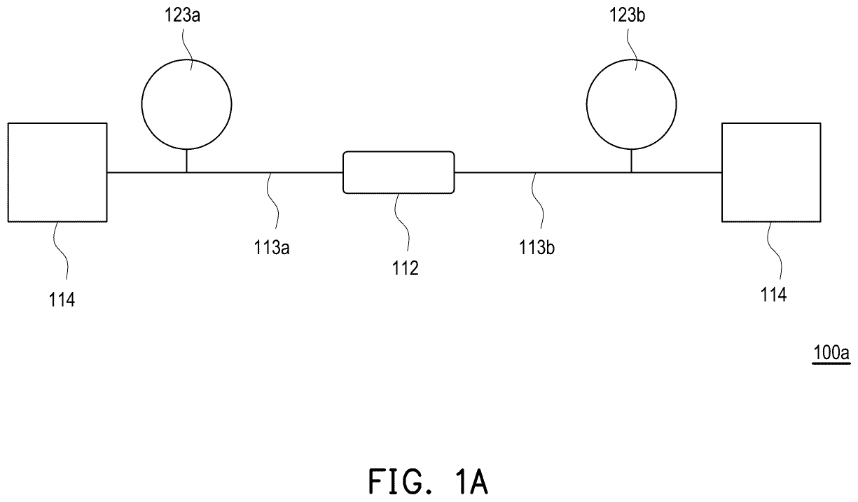

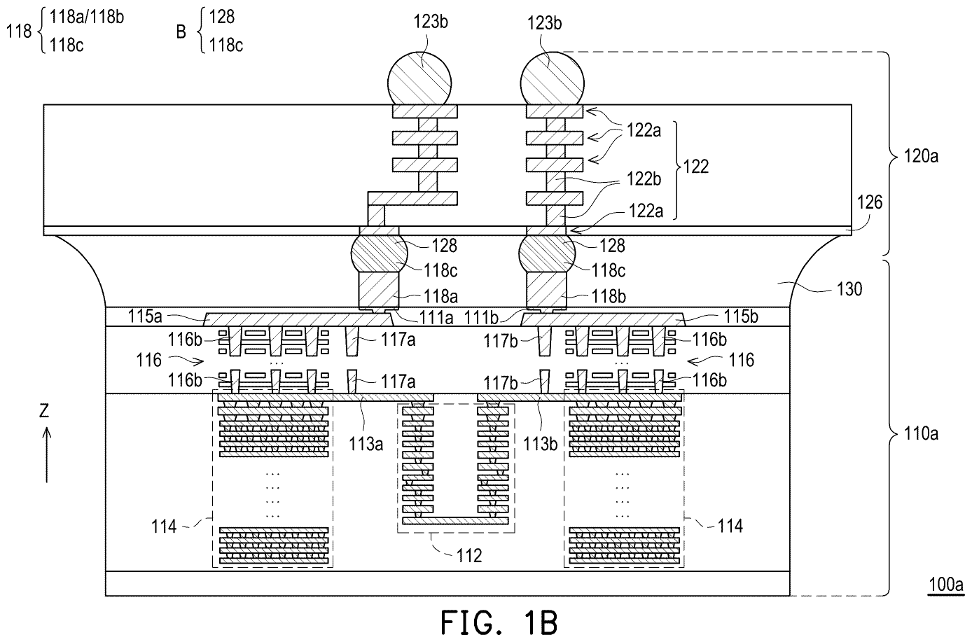

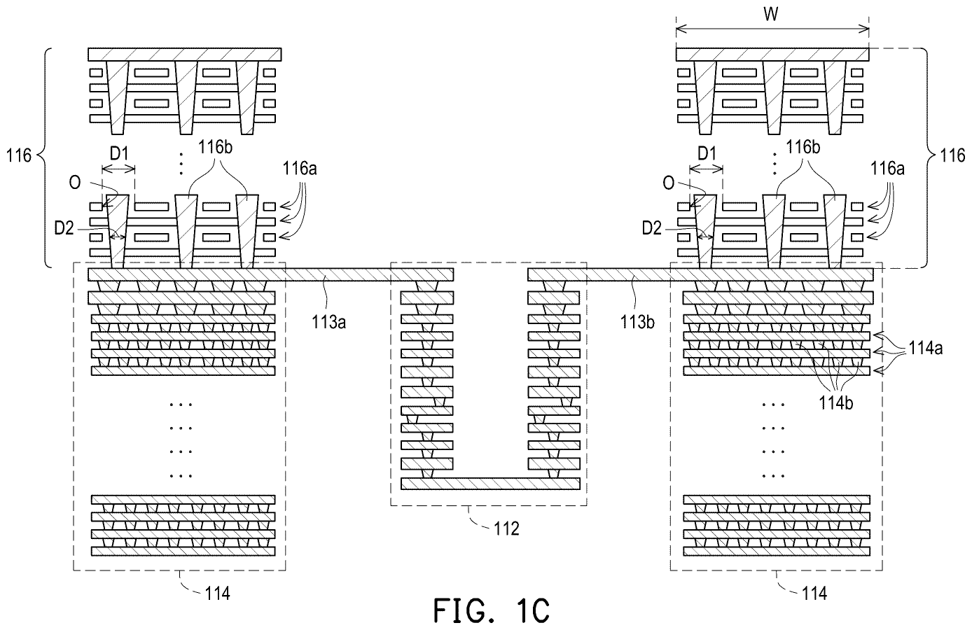

FIG. 1A is schematic view illustrating an integrated circuit package structure in accordance with some embodiments of the disclosure. FIG. 1B is a schematic cross-sectional view illustrating the integrated circuit package structure of FIG. 1A. FIG. 1C is a schematic enlarged partial view illustrating the integrated circuit package structure of FIG. 1B.

Referring to both FIG. 1A and FIG. 1B, an integrated circuit package structure 100a includes a first substrate 110a and a second substrate 120a. The first substrate 110a includes a sensor 112 and at least one metal routing (two metal routings 113a, 113b are schematically shown) connecting to the sensor 112. The second substrate 120a is bonded to the first substrate 110a and includes a circuit layer 122 and a plurality of conductive connectors (two conductive connectors 123a, 123b are schematically shown) connecting to the circuit layer 122. At least one of the first substrate 110a and the second substrate 120a further includes at least one stacked metal structure (two stacked metal structures 114 are schematically shown) configured to provide electrostatic discharge protection. In the present embodiment, the first substrate 110a includes the stacked metal structures 114 connecting to the sensor 112 via the metal routings 113a, 113b, but not limited to.

In some embodiments, the first substrate 110a is a bulk silicon (Si) substrate. Alternatively, the first substrate 110a may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, the first substrate 110a includes one or more group III-V materials, one or more group II-VI materials, or combinations thereof. In still some instances, the first substrate 110a is a semiconductor-on-insulator substrate, such as a silicon-on-insulator (SOI) substrate, a silicon germanium-on-insulator (SGOI) substrate, or a germanium-on-insulator (GeOI) substrate. In still some embodiments, the first substrate 110a is diamond substrate or a sapphire substrate.

The sensor 112 may be or comprise, for example, an electrical sensor (e.g., voltage sensor, current sensor, etc.). In some embodiments, each of the metal routings 113a, 113b is referred to as one or more redistribution layers (RDLs). In some embodiments, each of the metal routings 113a, 113b includes one or more coppers or copper alloys and is formed using one or more single or dual damascene processes. In some embodiments, each of the metal routings 113a, 113b includes one or more layers of metallic materials such as aluminum, copper, tungsten, titanium, tantalum, titanium nitride, tantalum nitride, nickel silicon, siliconized cobalt, other suitable conductive materials, or combinations thereof. Other configurations, arrangements, layers, or materials of each of the metal routings 113a, 113b are within the scope of this disclosure.

Each of the stacked metal structures 114 includes a plurality of metal layers 114a and a plurality of metal vias 114b connecting the metal layers 114a. In some embodiments, the material of the metal layers 114a include aluminum, titanium, copper, nickel, tungsten, or alloys thereof. The metal layers 114a may be formed by, for example, electroplating, deposition, and/or lithography and etching. In some embodiments, a via density of each layer of the metal vias 114b is greater than 0.01%. In some embodiments, the via density refers to the total vias (i.e. the metal vias 114b) area divided by the total metal area (i.e. the metal area of one metal layer 114a where the meal vias 114b land on). The metal vias 114b may be or include aluminum, titanium, copper, nickel, tungsten, or alloys thereof, and formed by an electroplating process, for example a single damascene Cu-process. In some embodiments, an area of each of the stacked metal structures 114 is greater than 3×10⁴ μm². In some embodiments, a volume of each of the stacked metal structures 114 is between 1.5×10⁴ μm³ and 7.5×10⁴ μm³. Other configurations, arrangements, layers, or materials of the stacked metal structures 114 are within the scope of this disclosure.

In some embodiment, the second substrate 120a includes at least one stacked metal structures. In some embodiment, the first substrate 110a and the second substrate 120a respectively include at least one stacked metal structures. That is to say, as long as at least one of the first substrate 110a and the second substrate 120a includes at least one stacked metal structure configured to provide electrostatic discharge protection, it is within the scope of the present disclosure to be protected. Other configurations, arrangements, layers, or materials of the stacked metal structures are within the scope of this disclosure. In some embodiments, the number of the metal routings and the stacked metal structures is one each, and the metal routing connects the sensor to the stacked metal structure.

Furthermore, referring to both FIG. 1B and FIG. 1C, the first substrate 110a further includes at least one capacitor structure (two capacitor structures 116 are schematically shown), and the capacitor structures 116 are electrically connected to the stacked metal structures 114, respectively. Herein, the stacked metal structures 114 and the capacitor structures 116 are configured to provide electrostatic discharge protection. Each of the capacitor structures 116 includes a plurality of dielectric layers 116a and a plurality of conductive vias 116b penetrating through the dielectric layers 116a. In some embodiments, the dielectric layers 116a may each be or include, for example, a high-k dielectric material or some other suitable dielectric material. High-K dielectric material, as used and described herein, includes dielectric materials having a high dielectric constant, for example, a permittivity is greater than 10. The high-K dielectric layer may include hafnium oxide. Alternatively, the high-K dielectric layer may include other high-K dielectric materials, such as titanium oxide (TiO₂), hafnium zirconium oxide (HfZrO), tantalum oxide (Ta₂O₅), hafnium silicon oxide (HfSiO4), zirconium oxide (ZrO₂), zirconium silicon oxide (ZrSiO2), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K dielectric layer may be formed by ALD, physical vapor deposition (PVD), CVD, oxidation, and/or other suitable methods.

Furthermore, each of the dielectric layers 116a has a plurality of openings O, and each of the conductive vias 116b pass through the corresponding openings O of each of the dielectric layers 116a. In some embodiments, a diameter D1 of each of the openings O is between 1 μm and 10 μm. The conductive vias 116b contact the stacked metal structures 114, and the conductive vias 116b are electrically connected to the stacked metal structures 114. In some embodiments, a width D2 of each of the conductive vias 116b is between 1 μm and 10 μm. In some embodiments, a via density of the conductive vias 116b is between 0.1% and 10%. The conductive vias 116b may be or include aluminum, titanium, copper, nickel, tungsten, or alloys thereof, and formed by an electroplating process, for example a single damascene Cu-process. In some embodiments, a width W of each of the capacitor structures 116 is between 50 μm and 350 μm. The capacitor structures 116 are set to slow down the rate of current rise. In some embodiments, the number of the capacitor structures 116 is one. Other configurations, arrangements, layers, or materials of the capacitor structures 116 are within the scope of this disclosure.

Referring to both FIG. 1A and FIG. 1B, the first substrate 110a further includes a plurality under bump metallization patterns (two under-bump metallization patterns 111a, 111b are schematically shown), a plurality of connection lines (two connection lines 115a, 115b are schematically shown), a plurality of conductive connection vias (two conductive connection vias 117a, 117b are schematically shown) and a plurality of first bumps (two first bumps 118 are schematically shown). The conductive vias 116b and the conductive connection vias 117a, 117b are connected to the corresponding connection lines 115a, 115b. The under bump metallization patterns 111a, 111b are connected to the corresponding connection lines 115a, 115b and the corresponding first bumps 118. Namely, the under bump metallization patterns 111a, 111b are located between the connection lines 115a, 115b and the first bumps 118.

In some embodiments, each of the under bump metallization patterns 111a, 111b includes a seed layer and a conductive layer disposed on the seed layer. In some embodiments, a material of the seed layer is formed through a sputtering process, a physical vapor deposition (PVD) process, or the like. In some embodiments, the seed layer is constituted by two sub-layers. The first sub-layer may include titanium, titanium nitride, tantalum, tantalum nitride, other suitable materials, or a combination thereof. On the other hand, the second sub-layer may include copper, copper alloys, or other suitable choice of materials. In some embodiments, a material of the conductive layer includes copper, copper alloys, or the like. The conductive layer is formed by electroplating, deposition, immersion plating, or the like. In some embodiments, a material of the connection lines 115a, 115b includes copper, copper alloys, or the like. The connection lines 115a, 115b are formed by electroplating, deposition, immersion plating, or the like. The conductive connection vias 117a, 117b may be or include aluminum, titanium, copper, nickel, tungsten, or alloys thereof, and formed by an electroplating process, for example a single damascene Cu-process.

The first bumps 118 are disposed on the corresponding under bump metallization patterns 111a, 111b, respectively. The first bumps 118 are electrically connected to the corresponding under bump metallization patterns 111a, 111b. The first bumps 118 include copper pillars 118a, 118b and cap portions 118c located on the corresponding copper pillars 118a, 118b. The first bumps 118 may include controlled collapse of chip connection (C4) bump. The controlled collapse of chip connection (C4) bump can be formed by initially forming a tin layer by any suitable method (such as evaporation, plating, printing, solder transfer); and then performing a reflow to shape the material into the desired bump shape. In some embodiments, the above-mentioned controlled collapse of chip connection (C4) bump is lead-free controlled collapse of chip connection (C4) solder bump. In some other embodiments, the above-mentioned controlled collapse of chip connection (C4) bump includes copper pillar and lead-free solder cap covering the copper pillar. In some embodiments, the above-mentioned controlled collapse of chip connection (C4) bump includes a material such as tin, or other suitable materials, such as silver or copper. In an embodiment in which the controlled collapse of chip connection (C4) bump is a tin solder bump, the controlled collapse of chip connection (C4) bump may be formed by initially forming a layer of tin through any suitable method such as evaporation, electroplating, printing, solder transfer, ball placement, or the like. Once a layer of tin has been formed on the structure, a reflow is performed in order to shape the material into the bump shape with a diameter, e.g., of about 80 μm.

Referring to FIG. 1B, the first substrate 110a and the second substrate 120a are bonded to each other in a vertical direction (shown as “Z direction” in FIG. 1B) of the integrated circuit package structure 100a. The second substrate 120a may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the second substrate 120a may be a SOI substrate. Generally, an SOI substrate includes a layer of a semiconductor material such as epitaxial silicon, germanium, silicon germanium, SOI, SGOI, or combinations thereof. The second substrate 120a is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for the second substrate 120a.

The circuit layer 122 includes a plurality of circuits 122a and a plurality of conductive vias 122b connecting the circuits 122a. In some embodiments, the material of the circuits 122a includes aluminum, titanium, copper, nickel, tungsten, or alloys thereof. The circuits 122a may be formed by, for example, electroplating, deposition, and/or lithography and etching. The conductive vias 122b may be or include aluminum, titanium, copper, nickel, tungsten, or alloys thereof, and formed by an electroplating process, for example a single damascene Cu-process. Other configurations, arrangements, layers, or materials of the circuit layer 122 are within the scope of this disclosure.

The first conductive connectors 123a, 123b are disposed on the circuit layer 122 and electrically connected to the first conductive connectors 123a, 123b. The first conductive connectors 123a, 123b may be ball grid array (BGA) connectors, solder balls, metal pillars, controlled collapse chip connection bumps, micro bumps, electroless nickel-electroless palladium-immersion gold technique (ENEPIG) formed bumps, or the like. The first conductive connectors 123a, 123b may include a conductive material such as solder, copper, aluminum, gold, nickel, silver, palladium, tin, the like, or a combination thereof. In some embodiments, the first conductive connectors 123a, 123b are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the first conductive connectors 123a, 123b are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the first conductive connectors 123a, 123b. The metal cap layer may include nickel, tin, tin-lead, gold, silver, palladium, indium, nickel-palladium-gold, nickel-gold, the like, or a combination thereof and may be formed by a plating process.

Referring to FIG. 1B again, the second substrate 120a further includes a solder resist coating (also referred to as solder mask) 126. The solder resist coating 126 has a plurality of openings to expose underlying circuit 122a, which also act as bump pads. The second substrate 120a further includes a plurality of second bumps 128, and the second bumps 128 are disposed on the bump pads, respectively. The second bumps 128 respectively connect to the first bumps 118 to electrically connect the second substrate 120a to the first substrate 110a. The second bumps 128 may be controlled collapse chip connection bumps, micro bumps, electroless nickel-electroless palladium-immersion gold technique (ENEPIG) formed bumps, or the like. The second bumps 128 may include a conductive material such as solder, copper, aluminum, gold, nickel, silver, palladium, tin, the like, or a combination thereof. In some embodiments, the second bumps 128 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the second bumps 128 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In the present embodiment, after the second substrate 120a is bonded to the first substrate 110a, the second bumps 128 and the corresponding cap portions 118c of the first bumps 118 are formed the solder bumps B.

Herein, the sensor 112, the metal routings 113a, 113b, the conductive connection vias 117a, 117b, the connection lines 115a, 115b, the under bump metallization patterns 111a, 111b, the copper pillars 118a, 118b, the circuit layer 122 and the first conductive connectors 123a, 123b are defined as a daisy chain. Electrical current can enter the integrated circuit package structure 100a from one of the first conductive connectors 123a and flow sequentially through the circuit layer 122, one of the copper pillars 118a, one of the under bump metallization patterns 111a, one of the connection lines 115a, one of the conductive connection vias 117a, one of the metal routings 113a, the sensor 112, the other of the metal routings 113b, the other of the conductive connection vias 117b, the other of the connection lines 115b, the other of the under bump metallization patterns 111b, the other of the copper pillar 118b, the circuit layer 122, and out of the other of the first conductive connectors 123b to complete the electrical test.

Furthermore, the integrated circuit package structure 100a of present embodiment achieves the electrostatic discharge protection by providing the current shunt path through the stacked metal structures 114 to discharge the electrostatic discharge currents. The stacked metal structures 114 and the capacitor structures 116 can be regarded as low impedance and high capacitance structure, which can replace the existing technology of diodes for electrostatic discharge protection, and can effectively protect the sensor 112.

Referring to FIG. 1B again, the integrated circuit package structure 100a further includes an underfill 130 disposed between the first substrate 110a and the second substrate 120a to cover the first bumps 118 and the second bumps 128. In some embodiments, the underfill 130 is located between the solder resist coating 126 and the under-bump metallization patterns 111a, 111b, and exposed a portion of the surface of the solder resist coating 126. In some embodiments, the underfill 130 is located between the solder resist coating 126 and the under-bump metallization patterns 111a, 111b, and completely covers the surface of the solder resist coating 126. In some embodiments, the underfill 130 extends from the solder resist coating 126 to cover a portion of the surrounding sidewalls of the first substrate 110a. In some embodiments, the underfill 130 extends to the height of the corresponding the capacitor structures 116. In some embodiments, the underfill 130 extends to the height of the corresponding the stacked metal structures 114. The location of the underfill 130 may vary based on product requirements and/or manufacturing processes. In some embodiments, the material of the underfill 130 is an insulating material and include a resin (e.g., epoxy resin), a filler material, a stress release agent (SRA), an adhesion promoter, other material, or a combination thereof. In some alternative embodiments, formation of the underfill 130 may be omitted.

The integrated circuit package structure 100a of present embodiment achieves the electrostatic discharge protection by providing the current shunt path through the stacked metal structures 114 to discharge the electrostatic discharge currents and the capacitor structures 116 to slow down the current rise rate. In other words, the integrated circuit package structure 100a of the present embodiment utilizes the special layout configuration to achieve electrostatic discharge protection even without the diode to ground. In brief, this embodiment utilizes fundamental electrostatic discharge concepts to design a structure with low impedance and high capacitance, thereby optimizing the charging distribution behavior and, consequently, indirectly protecting the sensor 112. Without increasing process cost and cycle time, the resistance of the sensor 112 was enhanced. In addition, the integrated circuit package structure 100a may be incorporated into a package structure such as a System-on-Integrated-Chip (SoIC), Chip-on-Wafer-on-Substrate (CoWoS®), Integrated Fan-Out package on package (InFO-POP), or the like. All suitable package structures or variations thereof of considered within the scope of the present disclosure.

In some embodiments, the System-on-Integrated-Chip (SoIC) package includes an interposer, an SoIC component disposed on and electrically connected to the interposer, memory stacks disposed on and electrically connected to the interposer, an underfill, a circuit substrate having conductive terminals, and conductive terminals. The interposer may be a silicon interposer. The memory stacks may be a high bandwidth memory (HBM) cubes including stacked high bandwidth memory dies. The SoIC component D1 and the memory stacks may be electrically connected to the interposer through micro-bumps encapsulated by the underfill. The interposer may be electrically connected to the circuit substrate through controlled collapse chip connection (C4) bumps. The conductive terminals may be ball grid array (BGA) balls.

In some embodiments, the Chip-on-Wafer-on-Substrate (CoWoS®) package includes an interposer, a package substrate, a first bump array, a second bump array, a third bump array, and a pair of IC chip packages. The interposer overlies and is electrically coupled to the package substrate by the first bump array. Further, the interposer underlies and is electrically coupled to the pair of IC chip packages by the second bump array. The IC chip packages may, for example, correspond to a SoC package and a DRAM package. Alternatively, one or both of the IC chip packages may correspond to other suitable types of IC packages. The package substrate includes a plurality conductive trace defining conductive paths from the first bump array to the third bump array on an underside of the package substrate.

In some embodiments, the Integrated Fan-Out package on package (InFO-POP) includes an integrated fan-out structure, a first bump array, a second bump array and a second IC chip package. The integrated fan-out structure includes a molding compound, through vias, and a plurality of redistribution layers (RDLs). The molding compound is adjacent to a first IC chip package on sidewalls of the first IC chip package, and the RDLs are between the first bump array and the first IC chip package. The first IC chip package may, for example, be system on a chip (SoC) package or some other suitable type of IC chip package. The through vias extend through the molding compound from corresponding RDLs to the second bump array on an upper side of the integrated fan-out structure. The RDLs are in a fan-out dielectric layer and define conductive paths interconnecting the first bump array, the through vias, and pads of the first IC chip package. The second IC chip package overlies and is electrically coupled to the integrated fan-out structure through the second bump array. The second IC chip package has a larger size than the first IC chip package and may, for example, be a DRAM chip package, some other suitable type of memory chip package, or some other suitable type of IC chip package.

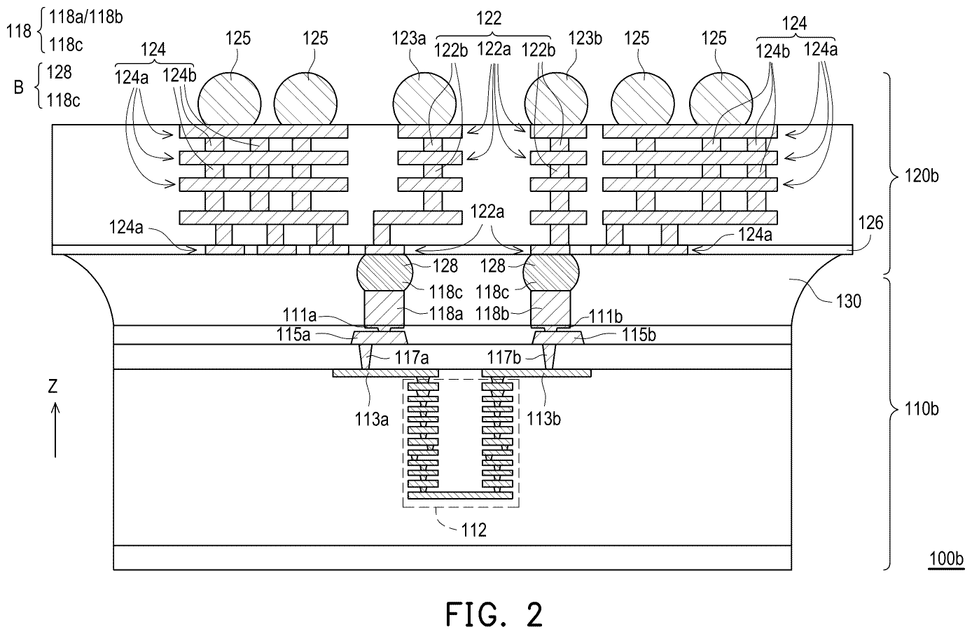

FIG. 2 is a schematic cross-sectional view illustrating an integrated circuit package structure in accordance with some alternative embodiments of the disclosure. Referring to FIG. 2, the integrated circuit package structure 100b in FIG. 2 is similar to the integrated circuit package structure 100a in FIG. 1B, so similar elements are denoted by the same reference numeral and the detailed description thereof is omitted herein. The difference between the integrated circuit package structure 100b in FIG. 2 and the integrated circuit package structure 100a in FIG. 1B lies in that in the integrated circuit package structure 100b, the first substrate 110b has no stacked metal structure and capacitor structures, and the second substrate 120b includes at least one stacked metal structure (two stacked metal structures 124 are schematically shown) disposed around the circuit layer 122. The stacked metal structures 124 are configured to provide electrostatic discharge protection.

In more detail, each of the stacked metal structures 124 includes a plurality of metal layers 124a and a plurality of metal vias 124b connecting the metal layers 124a. In some embodiments, the material of the metal layers 124a includes aluminum, titanium, copper, nickel, tungsten, or alloys thereof. The metal layers 124a may be formed by, for example, electroplating, deposition, and/or lithography and etching. The metal vias 124b may be or include aluminum, titanium, copper, nickel, tungsten, or alloys thereof, and formed by an electroplating process, for example a single damascene Cu-process. In some embodiments, a metal area of each of the stacked metal structures 124 is greater than or equal to 2×10⁶ μm². Other configurations, arrangements, layers, or materials of the stacked metal structures 124 are within the scope of this disclosure.

Furthermore, the second substrate 120b further includes a plurality of second conductive connectors 125 connecting to the stacked metal structures 124. In some embodiments, a number of the second conductive connectors 125 is greater than or equal to 4. The second conductive connectors 125 may be ball grid array (BGA) connectors, solder balls, metal pillars, controlled collapse chip connection bumps, micro bumps, electroless nickel-electroless palladium-immersion gold technique (ENEPIG) formed bumps, or the like. The second conductive connectors 125 may include a conductive material such as solder, copper, aluminum, gold, nickel, silver, palladium, tin, the like, or a combination thereof. In some embodiments, the second conductive connectors 125 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the second conductive connectors 125 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the second conductive connectors 125. The metal cap layer may include nickel, tin, tin-lead, gold, silver, palladium, indium, nickel-palladium-gold, nickel-gold, the like, or a combination thereof and may be formed by a plating process.

The integrated circuit package structure 100b of present embodiment achieves the electrostatic discharge protection by providing the current shunt path through the stacked metal structures 124 to discharge the electrostatic discharge currents. In other words, the integrated circuit package structure 100b of the present embodiment utilizes the special layout configuration to achieve electrostatic discharge protection even without the diode to ground. In brief, this embodiment utilizes fundamental electrostatic discharge concepts to design a structure with low impedance and high capacitance, thereby optimizing the charging distribution behavior and, consequently, indirectly protecting the sensor 112. Without increasing process cost and cycle time, the resistance of the sensor 112 was enhanced. In addition, the integrated circuit package structure 100b may be incorporated into a package structure such as a System-on-Integrated-Chip (SoIC), Chip-on-Wafer-on-Substrate (CoWoS®), Integrated Fan-Out package on package (InFO-POP), or the like. All suitable package structures or variations thereof of considered within the scope of the present disclosure.

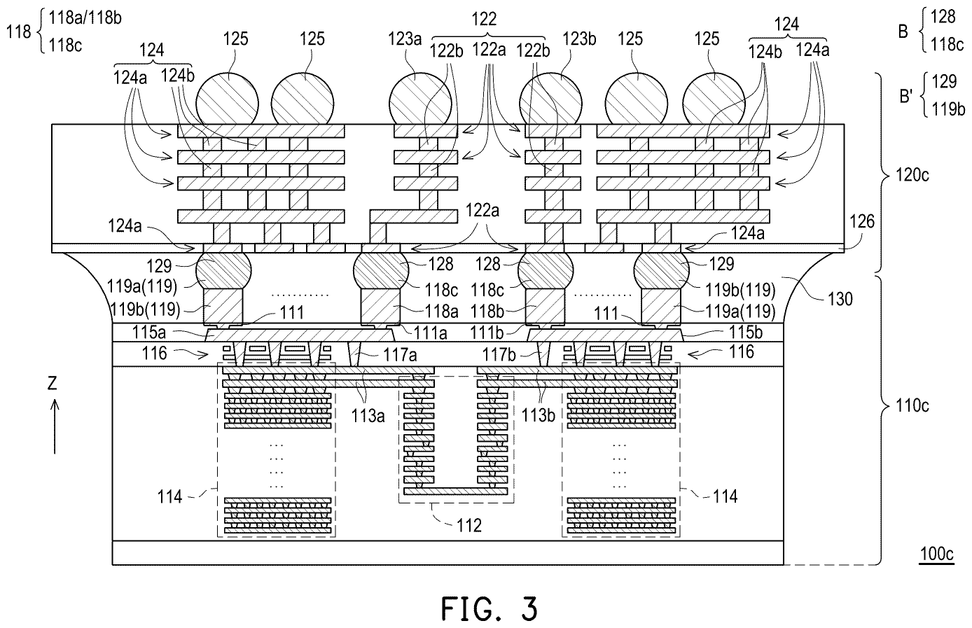

FIG. 3 is a schematic cross-sectional view illustrating an integrated circuit package structure in accordance with some alternative embodiments of the disclosure. Referring to FIG. 3, the integrated circuit package structure 100c in FIG. 3 is similar to the integrated circuit package structure 100a in FIG. 1B, so similar elements are denoted by the same reference numeral and the detailed description thereof is omitted herein. The difference between the integrated circuit package structure 100c in FIG. 3 and the integrated circuit package structure 100a in FIG. 1B lies in that in the integrated circuit package structure 100c, the second substrate 120c also further includes at least one stacked metal structure (two stacked metal structures 124 are schematically shown) disposed around the circuit layer 122. The stacked metal structures 114, the capacitor structures 116 and the stacked metal structures 124 are configured to provide electrostatic discharge protection.

In more detail, each of the stacked metal structures 124 includes a plurality of metal layers 124a and a plurality of metal vias 124b connecting the metal layers 124a. In some embodiments, the material of the metal layers 124a includes aluminum, titanium, copper, nickel, tungsten, or alloys thereof. The metal layers 124a may be formed by, for example, electroplating, deposition, and/or lithography and etching. The metal vias 124b may be or include aluminum, titanium, copper, nickel, tungsten, or alloys thereof, and formed by an electroplating process, for example a single damascene Cu-process. In some embodiments, a metal area of each of the stacked metal structures 124 is greater than or equal to 2×10⁶ μm². Other configurations, arrangements, layers, or materials of the stacked metal structures 124 are within the scope of this disclosure.

Herein, the integrated circuit package structure 100c of present embodiment achieves the electrostatic discharge protection by providing the current shunt path through the stacked metal structures 114 of first substrate 110c and the stacked metal structures 124 of the second substate 120c to discharge the electrostatic discharge currents. The stacked metal structures 114, the capacitor structures 116 and the stacked metal structures 124 can be regarded as low impedance and high capacitance structure, which can replace the existing technology of diodes for electrostatic discharge protection, and can effectively protect the sensor 112.

Furthermore, the second substrate 120c further includes a plurality of second conductive connectors 125 connecting to the stacked metal structures 124. In some embodiments, a number of the second conductive connectors 125 is greater than or equal to 4. The second conductive connectors 125 may be ball grid array (BGA) connectors, solder balls, metal pillars, controlled collapse chip connection bumps, micro bumps, electroless nickel-electroless palladium-immersion gold technique (ENEPIG) formed bumps, or the like. The second conductive connectors 125 may include a conductive material such as solder, copper, aluminum, gold, nickel, silver, palladium, tin, the like, or a combination thereof. In some embodiments, the second conductive connectors 125 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the second conductive connectors 125 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the second conductive connectors 125. The metal cap layer may include nickel, tin, tin-lead, gold, silver, palladium, indium, nickel-palladium-gold, nickel-gold, the like, or a combination thereof and may be formed by a plating process.

Furthermore, referring to FIG. 3 again, the first substrate 110c further includes a plurality of third bumps 119, and the second substrate 120c further includes a plurality of fourth bumps 129. The fourth bumps 129 connect to the third bumps 119 to electrically connect the second substrate 120b to the first substrate 110b. The third bumps 119 are disposed on the corresponding under bump metallization patterns 111, respectively, and surround the first bumps 118. Each of the third bumps 119 includes a copper pillar 119a and a cap portion 119b located on the corresponding copper pillar 119a. The third bumps 119 may include controlled collapse of chip connection (C4) bump. The controlled collapse of chip connection (C4) bump can be formed by initially forming a tin layer by any suitable method (such as evaporation, plating, printing, solder transfer); and then performing a reflow to shape the material into the desired bump shape. In some embodiments, the above-mentioned controlled collapse of chip connection (C4) bump is lead-free solder controlled collapse of chip connection (C4) bump. In some other embodiments, the above-mentioned controlled collapse of chip connection (C4) bump includes copper pillar and lead-free solder cap covering the copper pillar. In some embodiments, the above-mentioned controlled collapse of chip connection (C4) bump includes a material such as tin, or other suitable materials, such as silver or copper. In an embodiment in which the controlled collapse of chip connection (C4) bump is a tin solder bump, the controlled collapse of chip connection (C4) bump may be formed by initially forming a layer of tin through any suitable method such as evaporation, electroplating, printing, solder transfer, ball placement, or the like. Once a layer of tin has been formed on the structure, a reflow is performed in order to shape the material into the bump shape with a diameter, e.g., of about 80 μm. In some embodiments, a number of the third bumps 119 is greater than or equal to 10.

The fourth bumps 129 respectively connect to the third bumps 119 to electrically connect the second substrate 120c to the first substrate 110c. The fourth bumps 129 may be controlled collapse chip connection bumps, micro bumps, electroless nickel-electroless palladium-immersion gold technique (ENEPIG) formed bumps, or the like. The fourth bumps 129 may include a conductive material such as solder, copper, aluminum, gold, nickel, silver, palladium, tin, the like, or a combination thereof. In some embodiments, the fourth bumps 129 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the fourth bumps 129 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, a number of the fourth bumps 129 is greater than or equal to 10. In the present embodiment, after the second substrate 120c is bonded to the first substrate 110c, the fourth bumps 129 and the corresponding cap portions 119b of the third bumps 119 are formed the solder bumps B′.

The integrated circuit package structure 100c of present embodiment achieves the electrostatic discharge protection by providing the current shunt path through the stacked metal structures 114 of the first substrate 110c and the stacked metal structures 124 of the second substrate 120c to discharge the electrostatic discharge currents and the capacitor structures 116 to slow down the current rise rate. In other words, the integrated circuit package structure 100c of the present embodiment utilizes the special layout configuration to achieve electrostatic discharge protection even without the diode to ground. In brief, this embodiment utilizes fundamental electrostatic discharge concepts to design a structure with low impedance and high capacitance, thereby optimizing the charging distribution behavior and, consequently, indirectly protecting the sensor 112. Without increasing process cost and cycle time, the resistance of the sensor 112 was enhanced. In addition, the integrated circuit package structure 100c may be incorporated into a package structure such as a System-on-Integrated-Chip (SoIC), Chip-on-Wafer-on-Substrate (CoWoS), Integrated Fan-Out package on package (InFO-POP), or the like. All suitable package structures or variations thereof of considered within the scope of the present disclosure.

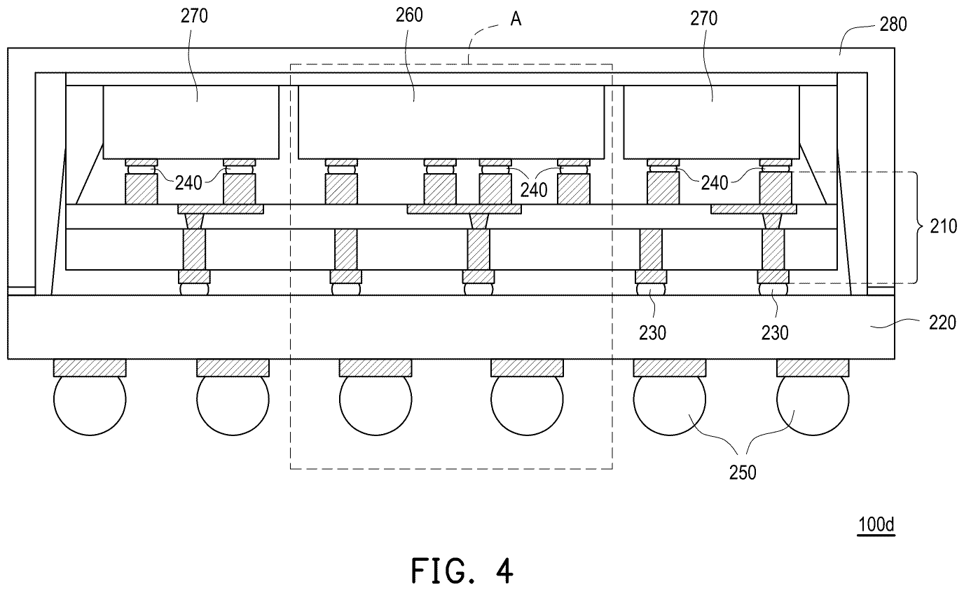

FIG. 4 is a schematic cross-sectional view illustrating an integrated circuit package structure in accordance with some alternative embodiments of the disclosure. Referring to FIG. 4, the integrated circuit package structure 100d in FIG. 4 is similar to the integrated circuit package structure 100a in FIG. 1B, so similar elements are denoted by the same reference numeral and the detailed description thereof is omitted herein. The difference between the integrated circuit package structure 100d in FIG. 4 and the integrated circuit package structure 100a in FIG. 1B lies in that in the integrated circuit package structure 100d includes an interposer 210, a package substrate 220, a first bump array 230, a second bump array 240, a third bump array 250, an IC chip package 260, two DRAM packages 270 and a cover 280. The interposer 210 overlies and is electrically coupled to the package substrate 220 by the first bump array 230. Further, the interposer 210 is electrically coupled to the IC chip package 260 and the two DRAM packages 270 by the second bump array 240. The IC chip package may, for example, be system on a chip (SoC) package or some other suitable type of IC chip package. In another embodiment, the package substrate 220 includes a plurality conductive trace defining conductive paths from the first bump array 230 to the third bump array 250 on an underside of the package substrate 220. In some embodiment, the components and their arrangement in area A is replaced by the integrated circuit package structure 100a in FIG. 1B or the integrated circuit package structure 100b in FIG. 2 or the integrated circuit package structure 100c in FIG. 3, according to the requirements. The cover 280 is bonded to the package substrate 220 to protect the interposer 210, the IC chip package 260 and the two DRAM packages 270.

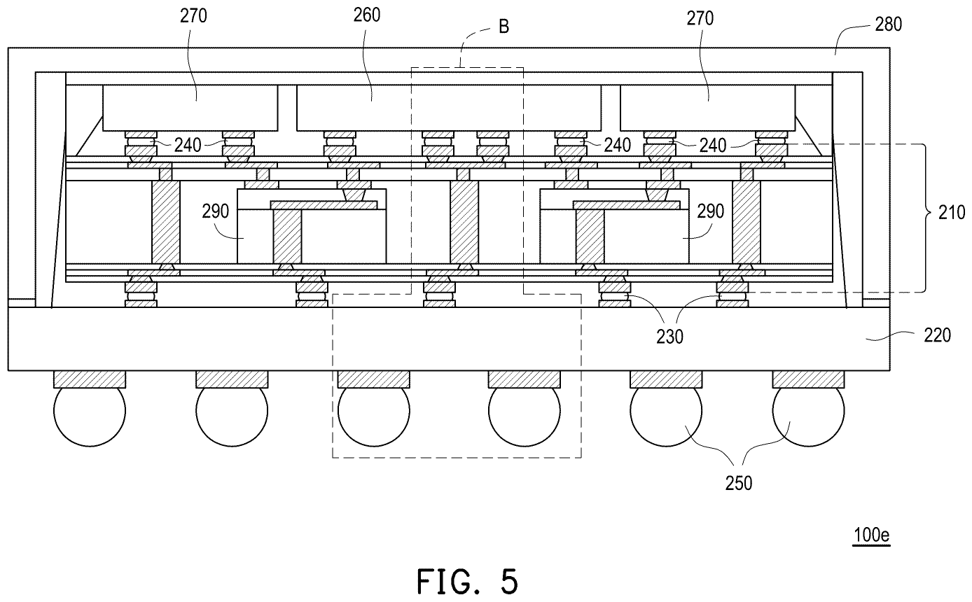

FIG. 5 is a schematic cross-sectional view illustrating an integrated circuit package structure in accordance with some alternative embodiments of the disclosure. Referring to FIG. 5, the integrated circuit package structure 100e in FIG. 5 is similar to the integrated circuit package structure 100d in FIG. 4, so similar elements are denoted by the same reference numeral and the detailed description thereof is omitted herein. The difference between the integrated circuit package structure 100e in FIG. 5 and the integrated circuit package structure 100d in FIG. 4 lies in that in the integrated circuit package structure 100e further includes two bridge chips 290 embedded in the interposer 210. One of the two bridge chips 290 is electrically connected to the IC chip package 260 and one of the two DRAM packages 270. The other one of the two bridge chips 290 is electrically connected to the IC chip package 260 and the other one of the two DRAM packages 270. In some embodiment, the components and their arrangement in area B is replaced by the integrated circuit package structure 100a in FIG. 1B or the integrated circuit package structure 100b in FIG. 2 or the integrated circuit package structure 100c in FIG. 3, according to the requirements.

In accordance with some embodiments of the disclosure, an integrated circuit package structure includes a first substrate and a second substrate. The first substrate includes a sensor and a metal routing connecting to the sensor. The second substrate is bonded to the first substrate and includes a circuit layer and a plurality of conductive connectors connecting to the circuit layer. At least one of the first substrate and the second substrate further includes a stacked metal structure configured to provide electrostatic discharge protection.

In accordance with some embodiments of the disclosure, an integrated circuit package structure includes a first substrate and a second substrate. The first substrate includes a sensor, a metal routing, a stacked metal structure and a capacitor structure. The metal routing connects the sensor and the stacked metal structure, and the capacitor structure is connected to the stacked metal structure. The stacked metal structure and the capacitor structure are configured to provide electrostatic discharge protection.

In accordance with some embodiments of the disclosure, a manufacturing method of an integrated circuit package structure includes providing a first substrate including a sensor, a metal routing, a first stacked metal structure and a capacitor structure, wherein the metal routing connects the sensor and the first stacked metal structure, and the capacitor structure is connected to the first stacked metal structure; and bonding the second substrate to the first substrate, wherein the second substrate includes a circuit layer, a plurality of first conductive connectors connecting to the circuit layer and a second stacked metal structure disposed around the circuit layer, and the first stacked metal structure, the capacitor structure and the second stacked metal structure are configured to provide electrostatic discharge protection.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package structure, comprising:
a first substrate comprising a sensor and a metal routing connecting to the sensor; and
a second substrate bonded to the first substrate and comprising a circuit layer and a plurality of conductive connectors connecting to the circuit layer,
wherein at least one of the first substrate and the second substrate further comprises a stacked metal structure configured to provide electrostatic discharge protection.

2. The integrated circuit package structure of claim 1, wherein the first substrate comprises the stacked metal structure connecting to the sensor via the metal routing.

3. The integrated circuit package structure of claim 2, wherein an area of the stacked metal structure is greater than 3×10⁴ μm².

4. The integrated circuit package structure of claim 2, wherein a volume of the stacked metal structure is between 1.5×10⁴ μm³ and 7.5×10⁴ μm³.

5. The integrated circuit package structure of claim 2, wherein the stacked metal structure comprises a plurality of metal layers and a plurality of metal vias connecting the plurality of metal layers, and a via density of each layer of the plurality of metal vias is greater than 0.01%.

6. The integrated circuit package structure of claim 1, wherein the second substrate comprises the stacked metal structure disposed around the circuit layer, and a metal area of the stacked metal structure is greater than or equal to 2×10⁶ μm².

7. An integrated circuit package structure, comprising:
a first substrate comprising a sensor, a metal routing, a stacked metal structure and a capacitor structure, wherein the metal routing connects the sensor and the stacked metal structure, and the capacitor structure is connected to the stacked metal structure, wherein the stacked metal structure and the capacitor structure are configured to provide electrostatic discharge protection; and
a second substrate bonded to the first substrate and comprising a circuit layer and a plurality of conductive connectors connecting to the circuit layer.

8. The integrated circuit package structure of claim 7, wherein a width of the capacitor structure is between 50 μm and 350 μm.

9. The integrated circuit package structure of claim 7, wherein the capacitor structure comprises a plurality of dielectric layers and a plurality of conductive vias penetrating through the plurality of dielectric layers.

10. The integrated circuit package structure of claim 9, wherein a permittivity of the plurality of dielectric layers is greater than 10.

11. The integrated circuit package structure of claim 9, wherein each of the plurality of dielectric layers has an opening, and a diameter of the opening is between 1 μm and 10 μm.

12. The integrated circuit package structure of claim 9, wherein a via density of the plurality of conductive vias is between 0.1% and 10%.

13. The integrated circuit package structure of claim 9, wherein a width of each of the plurality of conductive vias is between 1 μm and 10 μm.

14. The integrated circuit package structure of claim 7, wherein an area of the stacked metal structure is greater than 3×10⁴ μm².

15. The integrated circuit package structure of claim 7, wherein a volume of the stacked metal structure is between 1.5×10⁴ μm³ and 7.5×10⁴ μm³.

16. The integrated circuit package structure of claim 7, wherein the stacked metal structure comprises a plurality of metal layers and a plurality of metal vias connecting the plurality of metal layers, and a via density of each layer of the plurality of metal vias is greater than 0.01%.

17. A manufacturing method of an integrated circuit package structure, comprising:
providing a first substrate comprising a sensor, a metal routing, a first stacked metal structure and a capacitor structure, wherein the metal routing connects the sensor and the first stacked metal structure, and the capacitor structure is connected to the first stacked metal structure; and
bonding a second substrate to the first substrate, the second substrate comprising a circuit layer, a plurality of first conductive connectors connecting to the circuit layer and a second stacked metal structure disposed around the circuit layer, wherein the first stacked metal structure, the capacitor structure and the second stacked metal structure are configured to provide electrostatic discharge protection.

18. The manufacturing method of the integrated circuit package structure of claim 17, wherein the first substrate further comprises a plurality of first bumps, the second substrate further comprises a plurality of second bumps, and the plurality of second bumps connect to the plurality of first bumps to electrically connect the second substrate to the first substrate.

19. The manufacturing method of the integrated circuit package structure of claim 18, further comprising:
providing an underfill between the first substrate and the second substrate to cover the plurality of first bumps and the plurality of second bumps.

20. The manufacturing method of the integrated circuit package structure of claim 17, wherein the second substrate further comprises a plurality of second conductive connectors connecting to the second stacked metal structure, and a number of the plurality of second conductive connectors is greater than or equal to 4.
